(19) United States
(12) Patent Application Publication
(10) Pub. No.: US 2026/0136523 A1
(43) Pub. Date: May 14, 2026

(54) METHOD OF MANUFACTURING SEMICONDUCTOR DEVICE

(71) Applicant: SAMSUNG ELECTRONICS CO., LTD., Suwon-si (KR)

(72) Inventors: Sujin Kang, Suwon-si (KR); Heejae Chae, Suwon-si (KR); Yongkwan Kim, Suwon-si (KR); Huijung Kim, Suwon-si (KR); Hyunjin Lee, Suwon-si (KR); Inho Cha, Suwon-si (KR)

(21) Appl. No.: 19/222,955

(22) Filed: May 29, 2025

(30) Foreign Application Priority Data
Nov. 14, 2024 (KR) 10-2024-0162258

(51) Int. Cl. H10B 12/00

(52) U.S. Cl. CPC H10B 12/05; H10B 12/33

(57) ABSTRACT

An example method of manufacturing a semiconductor device is provided in which, after a sacrificial layer is formed on a vertical channel pattern of a plurality of vertical channel patterns, a source layer is formed on a side of the vertical channel pattern, and a junction region is formed on the vertical channel pattern.

### CROSS-REFERENCE TO RELATED APPLICATION

This application claims priority under 35 U.S.C. § 119 to Korean Patent Application No. 10-2024-0162258, filed on Nov. 14, 2024, in the Korean Intellectual Property office, the disclosure of which is incorporated by reference herein in its entirety.

### BACKGROUND

For good performance and economic feasibility, increasing a degree of integration of semiconductor devices is desired. In particular, the degree of integration of the memory devices is an important factor in determining the economic feasibility of a product. The degree of integration of a two-dimensional memory device is largely determined by the area occupied by unit memory cells, and thus, is greatly affected by the level of fine pattern formation technology. However, because expensive equipment is used to form fine patterns and the area of the chip die is limited, an increase in the degree of integration of the two-dimensional memory devices is limited.

### SUMMARY

The present disclosure relates to a semiconductor device with improved electrical reliability and performance.

In addition, the issues to be solved by the present disclosure are not limited to those mentioned above, and other issues may be clearly understood by those of ordinary skill in the art from the following descriptions.

In some implementations, a method of manufacturing a semiconductor device includes forming, on a first surface of a substrate including the first surface and a second facing the first surface, a plurality of vertical channel patterns apart from each other in a first horizontal direction, and a word line and a back gate electrode extending in a second horizontal direction crossing the first horizontal direction, forming a contact pattern layer including a plurality of first contact patterns in contact with one end portions of the plurality of vertical channel patterns and an isolation insulating layer between the plurality of first contact patterns, inverting the substrate such that the second surface of the substrate becomes an upper surface, removing the substrate, and etching an insulating pattern until other end portions of the plurality of vertical channel patterns are exposed, forming a sacrificial layer surrounding sidewalls and upper surfaces, which are exposed, of the plurality of vertical channel patterns, forming a source layer filling spaces between the sacrificial layers, forming a second contact pattern on the other end portions of the plurality of vertical channel patterns, and removing the sacrificial layer, and forming a bit line extending on the other end portions of the plurality of vertical channel patterns in the first horizontal direction, wherein the source layer is formed in a region where the source layer does not overlap (e.g., is offset from) the plurality of vertical channel patterns in a plan view, and wherein a dopant included in the second contact pattern diffuses from the source layer.

In some implementations, a method of manufacturing a semiconductor device includes forming, on a first surface of a substrate including the first surface and a second surface facing the first surface, a plurality of vertical channel patterns apart from each other in a first horizontal direction, a word line extending in a second horizontal direction crossing the first horizontal direction, between a first vertical channel pattern and a second vertical channel pattern facing each other among the plurality of vertical channel patterns, and a back gate electrode extending in the second horizontal direction between the second vertical channel pattern and a third vertical channel pattern facing each other among the plurality of vertical channel patterns, forming a contact pattern layer including a plurality of first contact patterns in contact with one end portions of the plurality of vertical channel patterns and an isolation insulating layer between the plurality of first contact patterns, inverting the substrate such that the second surface of the substrate becomes an upper surface, removing the substrate, and etching an insulating pattern until other end portions of the plurality of vertical channel patterns are exposed, forming a sacrificial layer surrounding sidewalls and upper surfaces, which are exposed, of the plurality of vertical channel patterns, and forming, on the sacrificial layer, a source layer filling a space between another end portion of a first vertical channel pattern and another end portion of a second vertical channel pattern, wherein the source layer includes a dopant, and the dopant passes through the sacrificial layer from the source layer, moves to another end portion of the vertical channel pattern, and forms a second contact pattern at the another end portion of the vertical channel pattern.

In some implementations, a method of manufacturing a semiconductor device includes forming, on a first surface of a substrate including the first surface and a second surface facing the first surface, a plurality of vertical channel patterns apart from each other in a first horizontal direction, a word line extending in a second horizontal direction crossing the first horizontal direction, between a first vertical channel pattern and a second vertical channel pattern facing each other among the plurality of vertical channel patterns, and a back gate electrode extending in the second horizontal direction, between the second vertical channel pattern and a third vertical channel pattern facing each other among the plurality of vertical channel patterns, forming a contact pattern layer including a plurality of first contact patterns in contact with one end portions of the plurality of vertical channel patterns and an isolation insulating layer between the plurality of first contact patterns, inverting the substrate such that the second surface of the substrate becomes an upper surface, removing the substrate, and etching an insulating pattern until other end portions of the plurality of vertical channel patterns are exposed, and forming a second contact pattern having a higher dopant concentration as vertical levels of other end portions of the plurality of vertical channel patterns increase, wherein the forming of the second contact pattern includes forming a sacrificial layer in a space between sidewalls and a source layer filling a space between the sacrificial layers, and diffusing the dopant from the source layer to the second contact pattern.

### BRIEF DESCRIPTION OF THE DRAWINGS

Implementations will be more clearly understood from the following detailed description taken in conjunction with the accompanying drawings.

FIG. 1 is a layout of an example of a semiconductor device.

FIG. 2 is an example cross-sectional view of the semiconductor device taken along line A-A′ in FIG. 1.

FIGS. 3, 4, 5, 6, 7, 8, 9, 10, 11, 12, 13A, 13B, 13C, 13D, 14A, 14B, 14C, 15A, 15B, 15C, 15D, 15E, 16A, and 16B are cross-sectional views illustrating an example of a method of manufacturing a semiconductor device.

### DETAILED DESCRIPTION

Hereinafter, implementations of the present disclosure are described in detail with reference to accompanying diagrams. Identical reference numerals are used for the same constituent devices in the drawings, and duplicate descriptions thereof are omitted.

Because various changes may be applied to the implementations and the present disclosure may have various implementations, particular implementations are illustrated in the diagrams and described in detail. However, this is not intended to limit the present disclosure to particular modes of practice, and it is to be appreciated that all changes, equivalents, and substitutes, which do not depart from the spirit and technical scope of the present disclosure, are encompassed in the present disclosure. In the description of the implementations, certain detailed explanations of the related art are omitted when it is deemed that they may unnecessarily obscure the essence of the implementations.

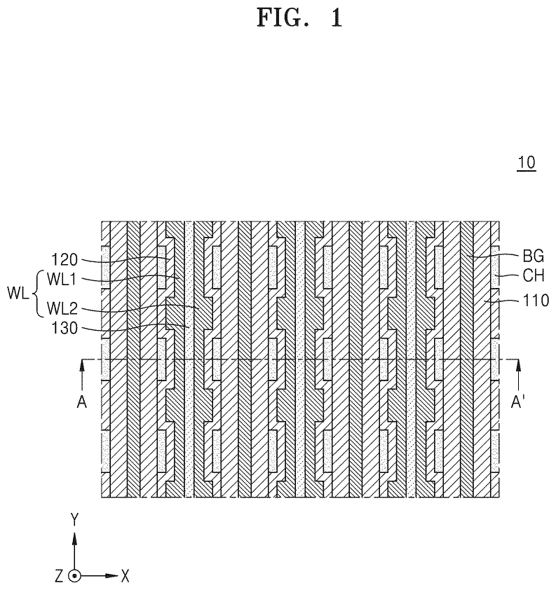

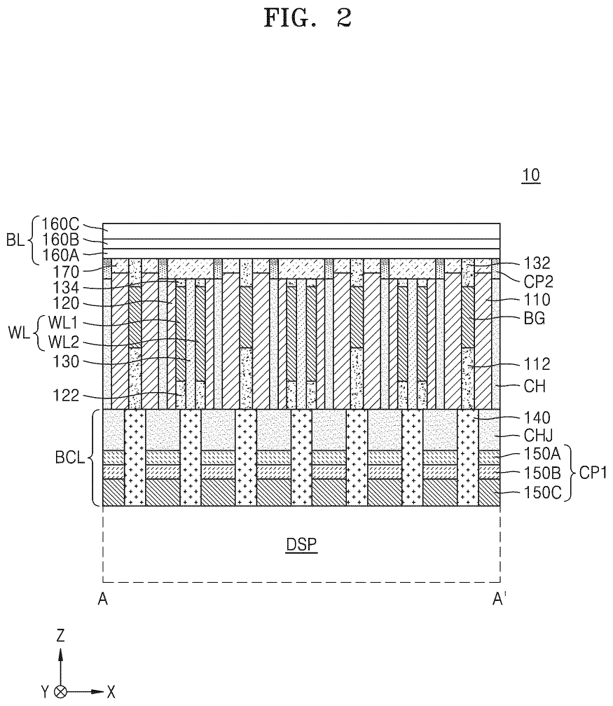

FIG. 1 is a layout of an example of a semiconductor device 10. FIG. 2 is an example cross-sectional view of the semiconductor device 10 taken along line A-A′ in FIG. 1.

Referring to FIGS. 1 and 2 together, the semiconductor device 10 may include memory cells including vertical channel transistors (VCT).

A bit line BL may extend in a first horizontal direction (X direction). The bit line BL may include a plurality of bit lines extending in the first horizontal direction (X direction) to be apart from each other in a second horizontal direction (Y direction) crossing the first horizontal direction (X direction).

The bit line BL may be formed in a stacked structure of first, second, and third conductive lines 160A, 160B, and 160C. In some implementations, the first conductive line 160A may include doped polysilicon. The second conductive line 160B may include metal silicide, such as titanium silicide, cobalt silicide, or nickel silicide. The third conductive line 160C may include a conductive metal nitride (for example, titanium nitride or tantalum nitride) or a metal (for example, tungsten, titanium, or tantalum).

A plurality of vertical channel patterns CH may be arranged apart from each other in the first horizontal direction (X direction). In addition, the plurality of vertical channel patterns CH may be arranged apart from each other at a certain interval in the second horizontal direction (Y direction). In other words, the plurality of vertical channel patterns CH may be two-dimensionally arranged in the first horizontal direction (X direction) and the second horizontal direction (Y direction) crossing each other. In some implementations, a second contact pattern CP2 may be formed on an upper portion of the plurality of vertical channel patterns CH, and the plurality of vertical channel patterns CH may be in contact with the bit line BL via the second contact pattern CP2.

The plurality of vertical channel patterns CH may include a single crystal semiconductor material layer. In some implementations, the plurality of vertical channel patterns CH may include single crystal silicon (Si) formed by using an epitaxial growth method. In other implementations, the plurality of vertical channel patterns CH may also include doped Si having a certain doping concentration in a certain conductivity type, by adjusting the dopant and/or doping concentration in the epitaxial growth process.

A word line WL may include a pair of first and second word lines WL1 and WL2 facing each other. The word lines WL may be arranged apart from each other below the bit line BL in the first horizontal direction (X direction), and extend in the second horizontal direction (Y direction).

In some implementations, the word line WL may have a vertical length less than a vertical length of the vertical channel pattern CH in a vertical direction (Z direction). In addition, the word line WL may have a vertical length greater than a vertical length of the back gate electrode BG, to be described below, in the vertical direction (Z direction).

The word line WL may include, for example, doped polysilicon, a metal, conductive metal nitride, conductive metal silicide, conductive metal oxide, or a combination thereof.

The back gate electrodes BG may be arranged, below the bit line BL, apart from each other at a certain interval in the first horizontal direction (X direction). The back gate electrode BG may extend in the second horizontal direction (Y direction). Each of the back gate electrodes BG may be arranged between the vertical channel patterns CH adjacent to each other.

A negative voltage may be applied to the back gate electrode BG when the semiconductor device 10 is operating, and the threshold voltage of a vertical channel transistor may be increased. In other words, the back gate electrode BG may prevent reduction in the leakage current characteristics due to a decrease in the threshold voltage as the vertical channel transistor becomes finer.

The back gate electrode BG may include, for example, doped polysilicon, conductive metal nitride (for example, titanium nitride or tantalum nitride), a metal (for example, tungsten, titanium, or tantalum), conductive metal silicide, conductive metal oxide, or a combination thereof.

A first insulating pattern 110 may be arranged between the plurality of vertical channel patterns CH and the back gate electrode BG adjacent to each other. The first insulating pattern 110 may include, for example, a silicon oxide layer, a silicon oxynitride layer, or a silicon nitride layer. The first insulating pattern 110 may be referred to as a back gate insulating pattern.

A second insulating pattern 120 may be arranged between the word line WL and the vertical channel pattern CH. The second insulating pattern 120 may extend in parallel with the word line WL in the second horizontal direction (Y direction). The second insulating pattern 120 may include a silicon oxide layer, a silicon oxynitride layer, a high dielectric layer having a dielectric constant higher than that of the silicon oxide layer, or a combination thereof. The high dielectric layer may include a metal oxide or a metal oxynitride. For example, the high dielectric layer usable for the second insulating pattern 120 may include HfO₂, HfSiO, HfSiON, HfTaO, HfTiO, HfZrO, ZrO₂, Al₂O₃, or a combination thereof, but is not limited thereto. The second insulating pattern 120 may be referred to as a gate dielectric layer.

A third insulating pattern 130 may be arranged between the first word line WL1 and the second word line WL2. In other words, the first and second word lines WL1 and WL2 may be electrically isolated by the third insulating pattern 130. In some implementations, an upper surface of the third insulating pattern 130 may be apart from the bit line BL, and a lower surface of the third insulating pattern 130 may be in contact with an isolation insulating layer 140 to be described below. The third insulating pattern 130 may include, for example, a silicon oxide layer, a silicon oxynitride layer, or a silicon nitride layer. The third insulating pattern 130 may be referred to as a word line insulating pattern.

A plurality of first contact patterns CP1 may penetrate the isolation insulating layer 140, and may be connected to each of a plurality of channel junctions CHJ respectively extending from the plurality of vertical channel patterns CH. In other words, the plurality of first contact patterns CP1 may be connected to the plurality of vertical channel patterns CH via the plurality of channel junctions CHJ, respectively. The first contact patterns CP1 adjacent to each other may be separated from each other by the isolation insulating layer 140. The first contact pattern CP1 may be referred to as a buried contact BC.

In the specification, for convenience of description, the plurality of channel junctions CHJ, the plurality of first contact patterns CP1, and the isolation insulating layer 140 may be referred to as a first contact pattern layer BCL.

Each of the plurality of first contact patterns CP1 may be formed in a stacked structure of first, second, and third conductive patterns 150A, 150B and 150C. In some implementations, the first conductive pattern 150A may include doped polysilicon. The second conductive pattern 150B may include metal silicide, such as titanium silicide, cobalt silicide, and nickel silicide. The third conductive pattern 150C may include a conductive metal nitride (for example, titanium nitride, or tantalum nitride) or a metal (for example, tungsten, titanium, or tantalum).

A data storage pattern DSP may be arranged under the first contact pattern CP1. The data storage pattern DSP may be electrically connected to the plurality of vertical channel patterns CH. Although not illustrated in detail, the data storage patterns DSP may be arranged in a matrix form in the first horizontal direction (X direction) and the second horizontal direction (Y direction).

In some implementations, the data storage pattern DSP may include a capacitor, and may include a capacitor dielectric layer arranged between a storage electrode and a plate electrode. In this case, the storage electrode may be in direct contact with the plurality of first contact patterns CP1.

In other implementations, the data storage pattern DSP may include a variable resistance pattern which may be switched by an electrical pulse applied to a memory device. For example, the data storage pattern DSP may include a phase-change material, a Perovskite compound, transition metal oxide, a magnetic material, a ferromagnetic material, an antiferromagnetic material, or the like, the crystal state of which changes according to the amount of current.

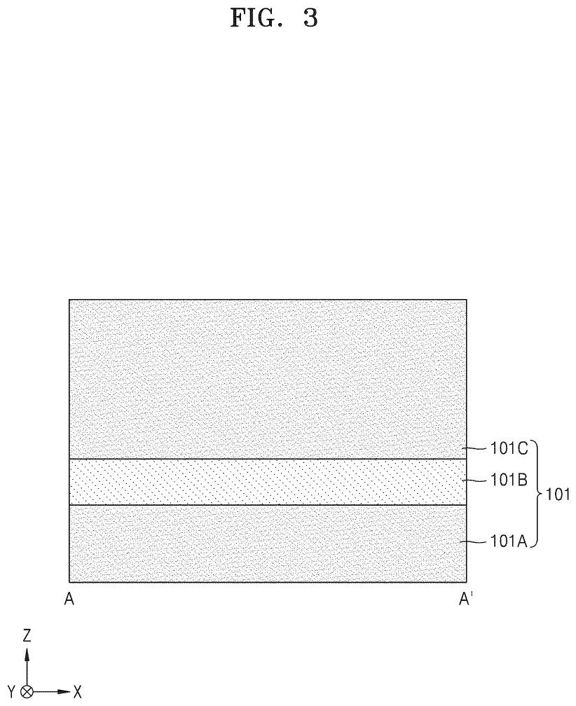

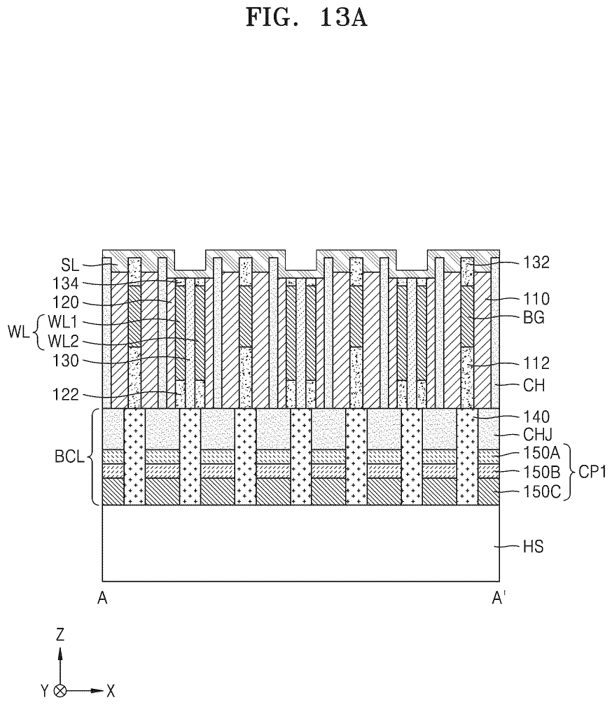

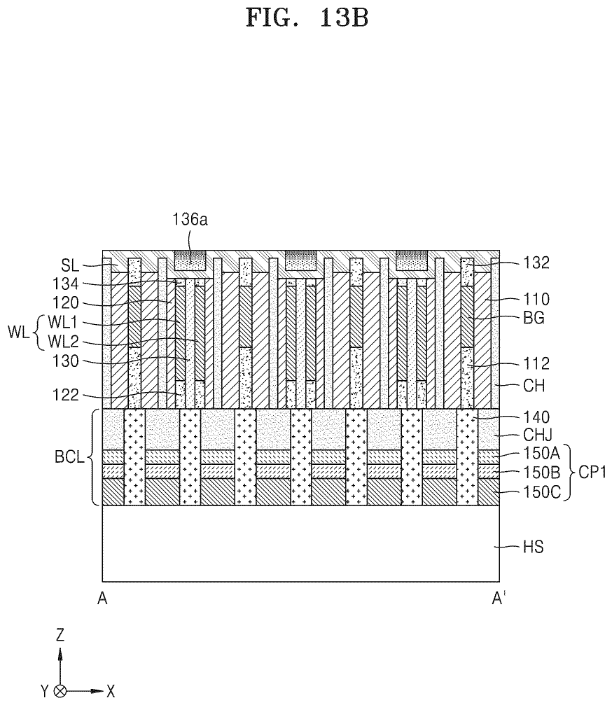

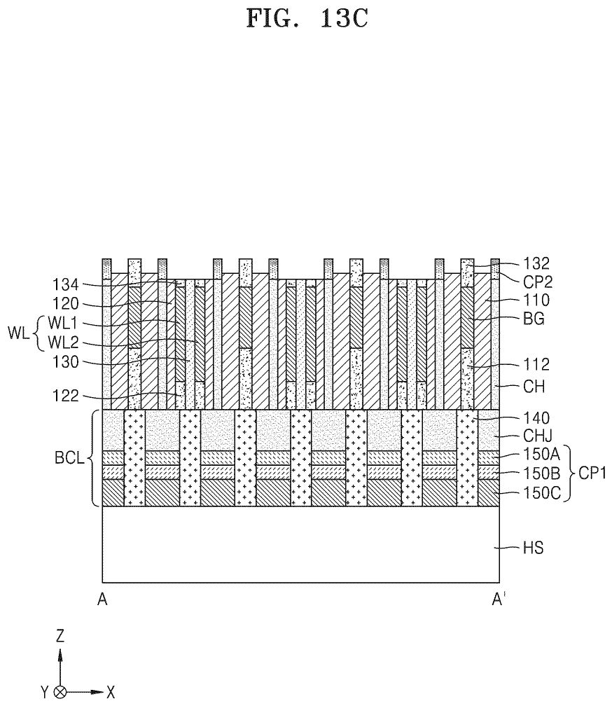

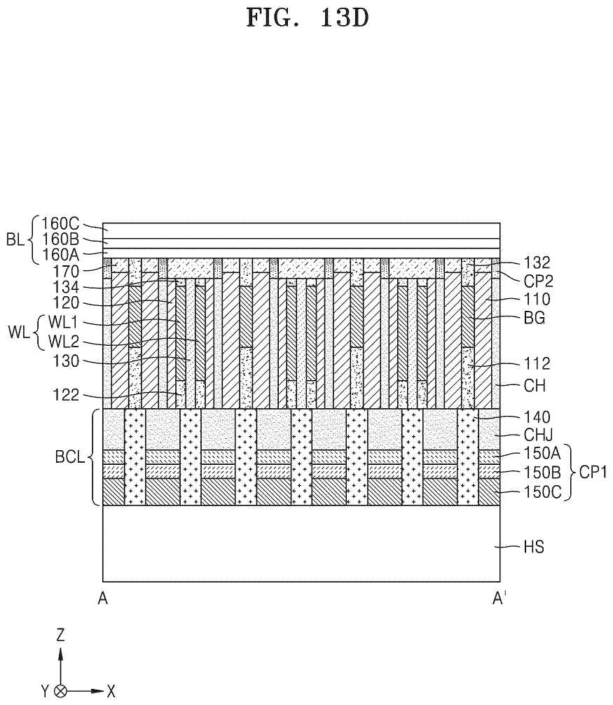

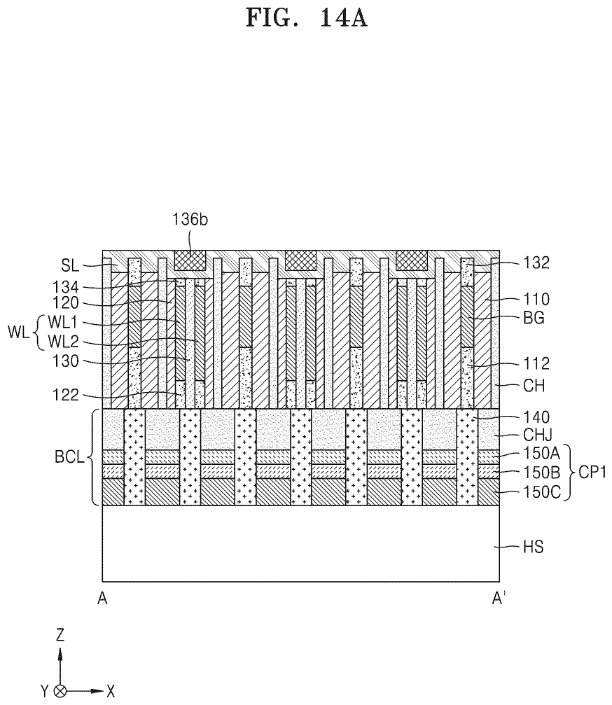

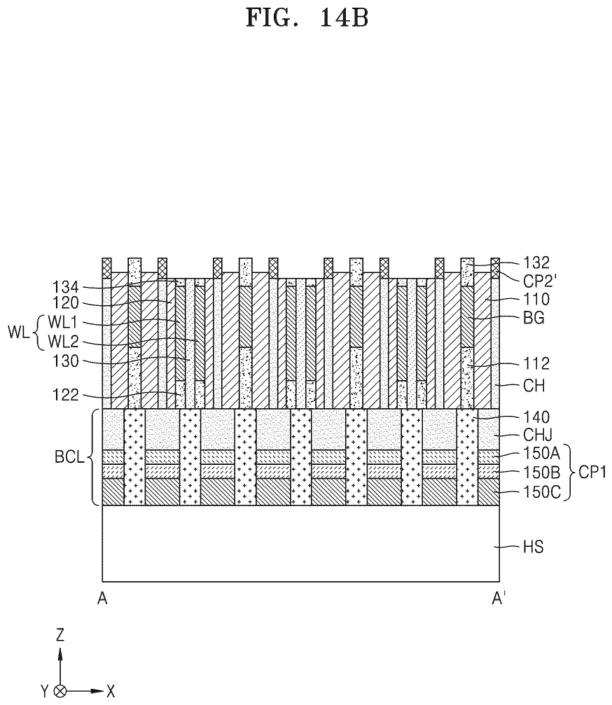

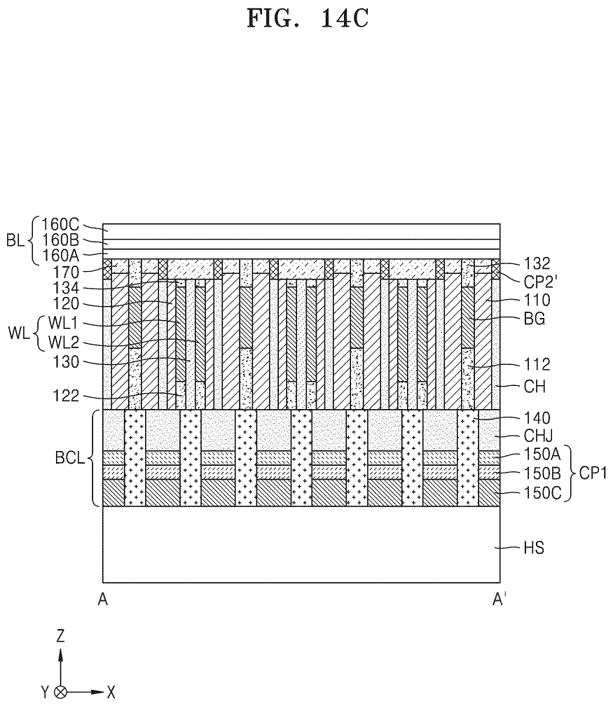

FIGS. 3, 4, 5, 6, 7, 8, 9, 10, 11, 12, 13A, 13B, 13C, 13D, 14A, 14B, 14C, 15A, 15B, 15C, 15D, 15E, 16A, and 16B are cross-sectional views illustrating an example of a method of manufacturing a semiconductor device 10. FIGS. 3 through 13D are cross-sectional views illustrating a method of manufacturing the semiconductor device 10, and each of FIGS. 14A through 14C, FIGS. 15A through 15E, and FIGS. 16A and 16B may be a cross-sectional view illustrating a portion of a method of manufacturing the semiconductor device 10 formed by a method different from the method described with reference to FIGS. 13A through 13D.

Referring to FIG. 3, a substrate structure 101 including a substrate layer 101A, an insulating layer 101B, and an active layer 101C may be prepared.

The substrate structure 101 may include a silicon on insulator (SOI) substrate. For example, the substrate layer 101A may include Si. The insulating layer 101B may include a silicon oxide layer. The active layer 101C may include a single crystal semiconductor material layer.

In some implementations, the active layer 101C may include single crystal Si formed by using an epitaxial growth method. In other implementations, the active layer 101C may also include doped Si having a certain doping concentration in a certain conductivity type, by adjusting the dopant and/or doping concentration in the epitaxial growth process.

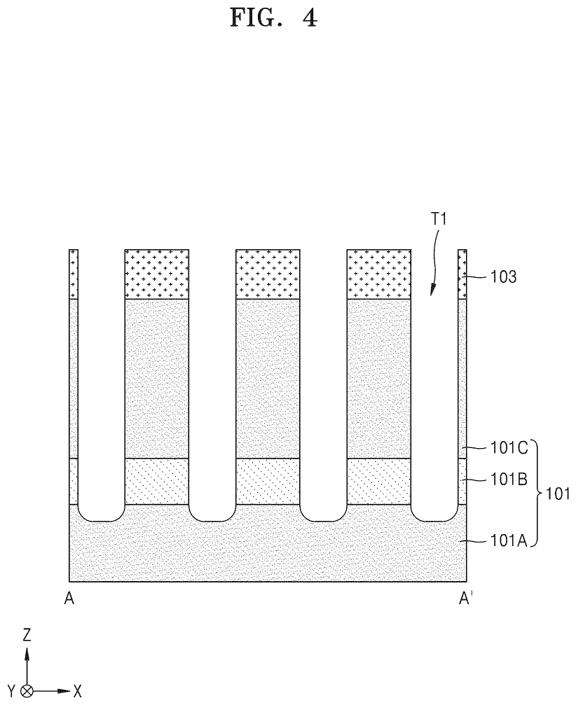

Referring to FIG. 4, a mask pattern 103 may be formed on the active layer 101C of the substrate structure 101.

The mask pattern 103 may include a silicon nitride layer. In some implementations, an oxide layer may also be arranged between the active layer 101C and the mask pattern 103.

Next, a plurality of first trenches T1 may be formed by etching the substrate structure 101, by using the mask pattern 103 as an etching mask. In some implementations, the plurality of first trenches T1 may be formed to penetrate the active layer 101C and the insulating layer 101B in the vertical direction (Z direction), etch a portion of the substrate layer 101A, and extend long in the second horizontal direction (Y direction).

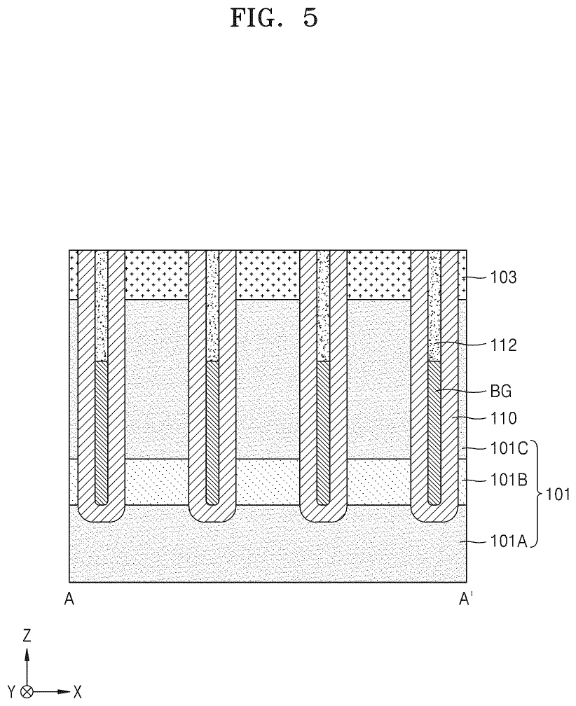

Referring to FIG. 5, a plurality of first insulating patterns 110 may be formed to conformally cover inner sidewalls of the plurality of first trenches T1.

Next, the back gate electrode BG may be formed to fill a lower space of each of the plurality of first trenches T1. In addition, a first back gate insulating layer 112 may be formed on the back gate electrode BG, to fill an upper space of each of the plurality of first trenches T1.

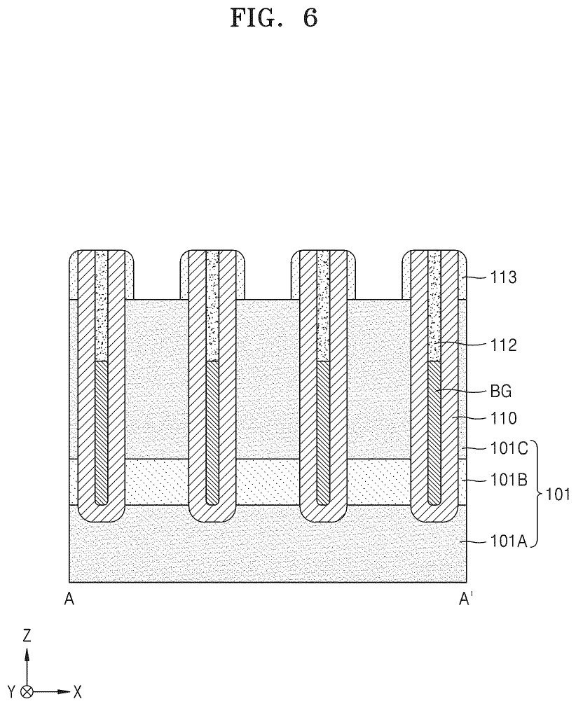

Referring to FIG. 6, by removing the mask pattern (refer to 103 in FIG. 5), an upper surface of the active layer 101C may be exposed.

Next, a plurality of spacers 113 covering an upper region of the plurality of first insulating patterns 110 and a portion of the upper surface of the active layer 101C arranged around each of the plurality of first insulating patterns 110 may be formed. Each of the plurality of spacers 113 may include, for example, a silicon oxide layer.

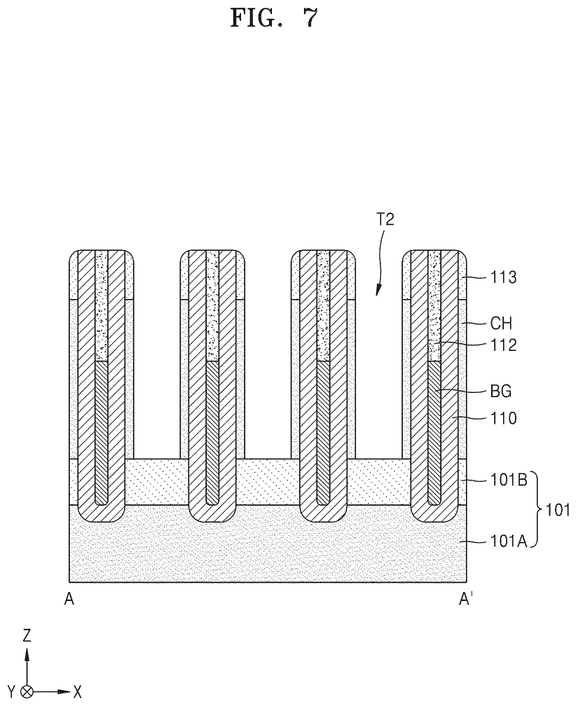

Referring to FIG. 7, a plurality of second trenches T2 may be formed by etching the active layer (refer to 101C in FIG. 6) by using the plurality of first insulating patterns 110, the first back gate insulating layer 112, and the plurality of spacers 113 as etching masks.

As a result, portions of the active layer (refer to 101C in FIG. 6) arranged under the plurality of spacers 113 may remain as the plurality of vertical channel patterns CH.

In some implementations, the insulating layer 101B may function as an etch stop layer, in the process of forming the plurality of second trenches T2.

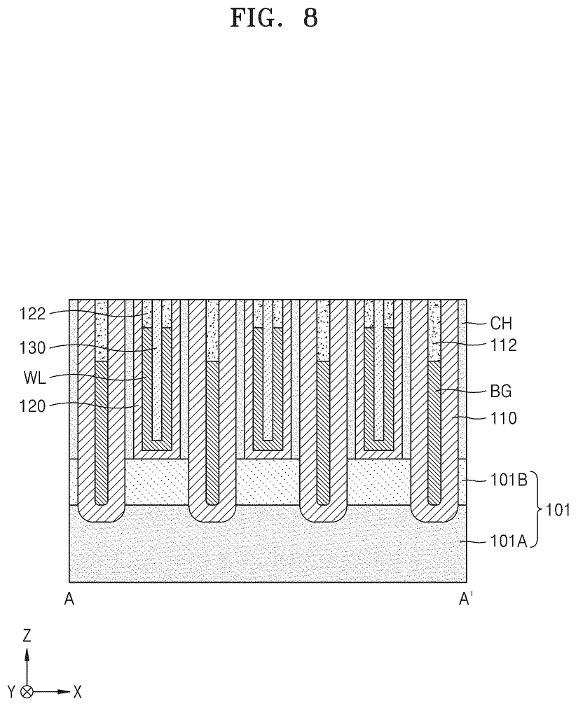

Referring to FIG. 8, the second insulating pattern 120 may be formed to conformally cover the inner sidewalls of the plurality of first trenches T1.

Next, the word line WL may be formed to conformally cover a portion of inner walls of the second insulating pattern 120, and a first buried pattern 122 may be formed on the word line WL to conformally cover the remaining portion of the inner walls thereof.

Next, the third insulating pattern 130 may be formed to fill spaces of the plurality of first trenches T1.

Next, a planarization process of etching a portion of the plurality of first insulating patterns 110, a portion of the first back gate insulating layer 112, and all of the plurality of spacers 113, which are arranged at vertical levels higher than the upper surface of the plurality of vertical channel patterns CH, may be performed.

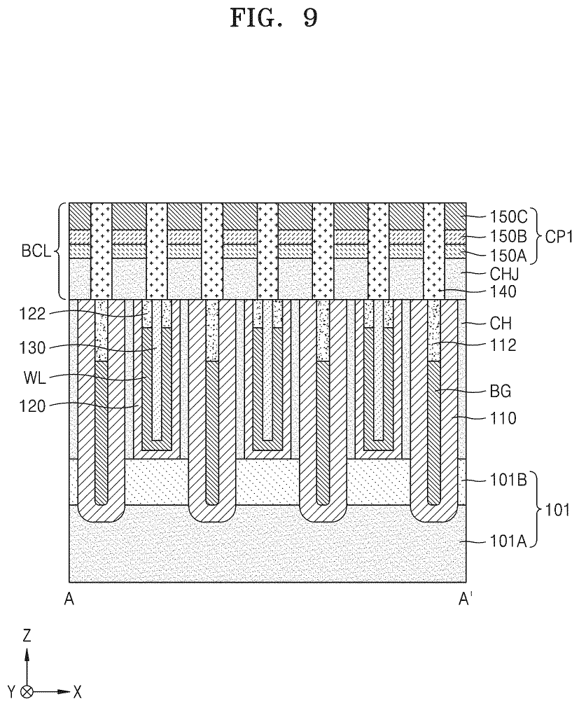

Referring to FIG. 9, a first contact pattern layer BCL including the isolation insulating layer 140, the plurality of channel junctions CHJ, and the plurality of first contact patterns CP1 may be formed on an upper surface of the resultant product of FIG. 8.

The isolation insulating layer 140 may be formed first, and the plurality of channel junctions CHJ and the plurality of first contact patterns CP1 may be formed to penetrate the isolation insulating layer 140. Accordingly, the first contact patterns CP1 adjacent to each other may be isolated by the isolation insulating layer 140. In addition, the plurality of first contact patterns CP1 may be formed to be electrically connected to the plurality of vertical channel patterns CH via the plurality of channel junctions CHJ.

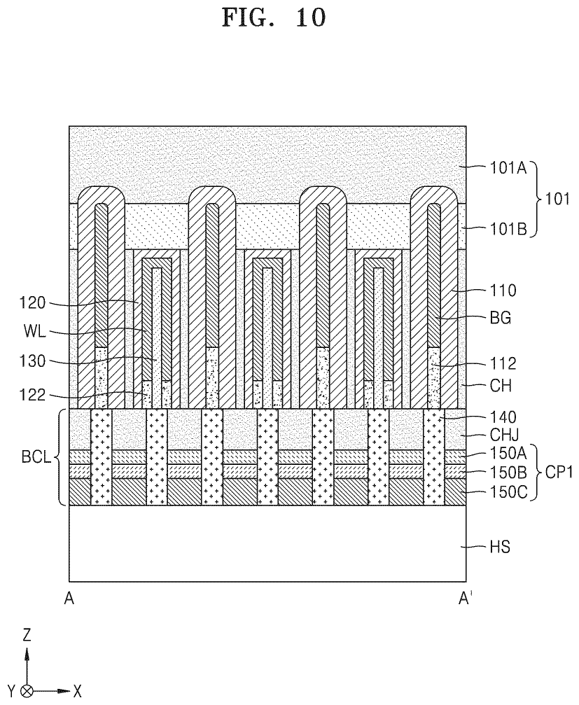

Referring to FIG. 10, a handling substrate HS may be attached to an upper surface of the first contact pattern layer BCL.

Next, by turning the result of FIG. 9 upside down such that the vertical direction (Z direction) is reversed, the substrate structure 101 may face upward, and the handling substrate HS may face downward.

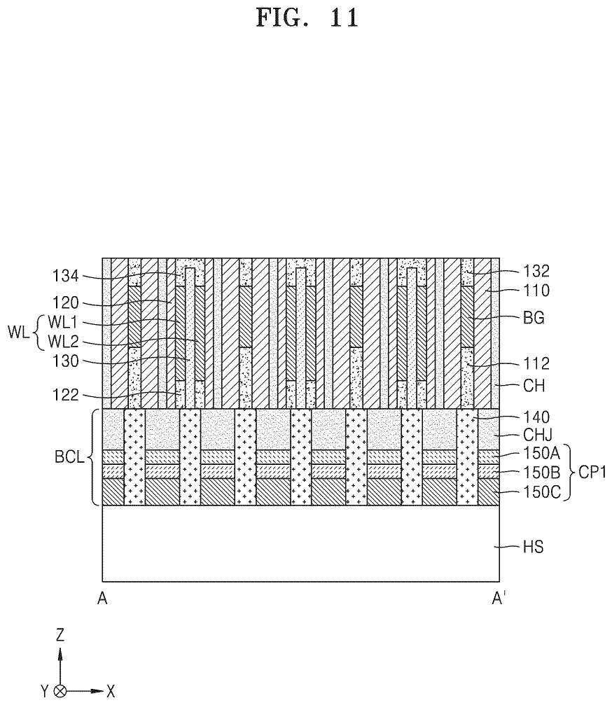

Referring to FIG. 11, a grinding process and a wet etching process may be sequentially performed from the upper surface of the substrate structure 101, until the uppermost surface of the word line WL is exposed.

Accordingly, the word line WL and the back gate electrode BG may be exposed. In addition, the first insulating pattern 110 and the second insulating pattern 120 may be exposed.

The plurality of vertical channel patterns CH may be exposed. Although not illustrated, in other implementations, upper portions of the plurality of vertical channel patterns CH may protrude upward.

Next, a portion of the exposed back gate electrode BG may be etched. In addition, by etching a portion of the exposed word line WL, the word line WL may be isolated into a pair of the first and second word lines WL1 and WL2 facing each other.

Next, a second back gate insulating layer 132 may be formed in a space in which the portion of the back gate electrode BG has been etched. In addition, a second buried pattern 134 may be formed in a space in which the portion of the word line WL has been etched.

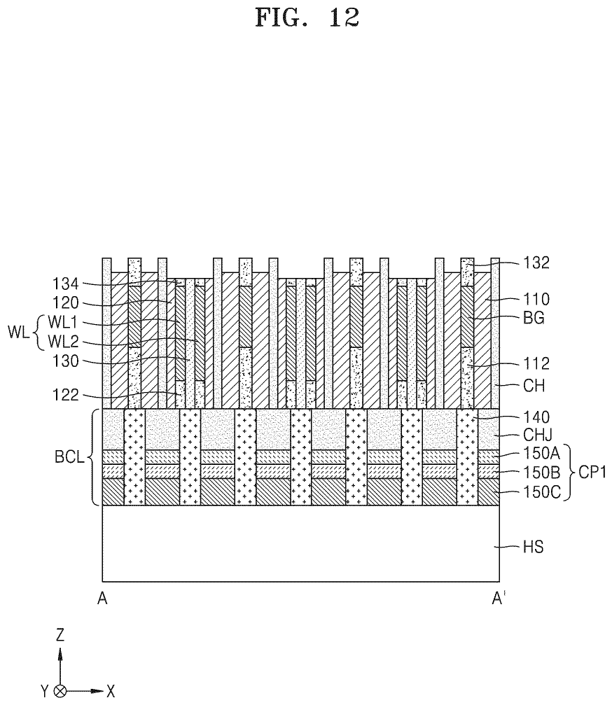

Referring to FIG. 12, portions of the first insulating pattern 110, the second insulating pattern 120, the third insulating pattern 130, and the second buried pattern 134 may be removed from the resultant product of FIG. 11.

In some implementations, vertical levels of the upper surfaces of the second insulating pattern 120, the third insulating pattern 130, and the second buried pattern 134 may be lower than a vertical level of the upper surface of the first insulating pattern 110 from which respective portions thereof has been removed. The reason may be because a distance between the second back gate insulating layer 132 and the vertical channel pattern CH, which are apart from each other in the first horizontal direction (X direction) with the first insulating pattern 110 arranged therebetween, is less than a distance between the vertical channel patterns CH apart from each other in the first horizontal direction (X direction) with the first and second word lines WL1 and WL2 arranged therebetween. As the width of a space between the vertical channel patterns CH in the first horizontal direction (X direction) increases, the depth of the space, in which the recess is formed, may increase.

Referring to FIG. 13A, a sacrificial layer SL may be formed on the resultant product of FIG. 12. In some implementations, the sacrificial layer SL may include silicon germanium (SiGe). The sacrificial layer SL may be formed to have a thickness to cover all upper surfaces of the first insulating pattern 110, the second insulating pattern 120, the third insulating pattern 130, the second back gate insulating layer 132, the second buried pattern 134, and the vertical channel pattern CH. In some implementations, a vertical level of an upper surface of the sacrificial layer SL formed in a space between vertical channel patterns CH apart from each other in the first horizontal direction (X direction) with the first and second word lines WL1 and WL2 arranged therebetween may be less than a vertical level of an upper surface of the sacrificial layer SL formed in a space between vertical channel patterns CH apart from each other in the first horizontal direction (X direction) with the back gate electrode BG arranged therebetween.

Referring to FIG. 13B, a source layer 136a filling a space between the sacrificial layers SL in FIG. 13A may be formed. In some implementations, the source layer 136a may include doped polysilicon, and the dopant included in the source layer 136a may be at a higher concentration farther away from an upper surface of the handling substrate HS in the vertical direction (Z direction).

Referring to FIG. 13C, the second contact pattern CP2 having a constant concentration gradient may be formed on the vertical channel pattern CH due to the dopant diffused from the source layer 136a, and the sacrificial layer SL may be removed again.

The dopant included in the second contact pattern CP2 may move from the source layer 136a by using, for example, an ion implantation process, but the present disclosure is not limited thereto. In some implementations, the dopant included in the second contact pattern CP2 may include phosphorus (P).

In some implementations, the dopant included in the second contact pattern CP2 may be included at a higher concentration farther away from the upper surface of the handling substrate HS in the vertical direction (Z direction).

Referring to FIG. 13D, the bit line BL including the first, second, and third conductive lines 160A, 160B, and 160C may be formed on the resultant product of FIG. 13C.

The bit line BL may be formed to extend in the first horizontal direction (X direction). The bit line BL may extend in the first horizontal direction (X direction), and may be formed in plurality apart from each other in the second horizontal direction (Y direction) crossing the first horizontal direction (X direction).

Before the bit line BL is formed, a capping insulating pattern 170 filling a space between the second back gate insulating layer 132, the second contact pattern CP2, and the first insulating pattern 110 and a space between upper surfaces of the first and second word lines WL1 and WL2 and the second contact pattern CP2 adjacent thereto with the first and second word lines WL1 and WL2 arranged therebetween may be formed. In some implementations, the capping insulating pattern 170 may include oxide. The upper surface of the capping insulating pattern 170 may be arranged on the same plane as the upper surfaces of the second contact pattern CP2 and the second back gate insulating layer 132, and may be in contact with the lower surface of the bit line BL.

Referring to FIG. 2 again, the handling substrate HS may be removed from the resultant product of FIG. 13D, and the data storage pattern DSP may be formed under a contact pattern layer BCL. The data storage pattern DSP may be electrically connected to the plurality of vertical channel patterns CH.

By using the method of manufacturing the semiconductor device 10 described above, the semiconductor device 10 may be manufactured. The semiconductor device 10 may deposit the sacrificial layer SL onto the vertical channel pattern CH, form the source layer 136a including the dopant in the lateral direction of the vertical channel pattern CH, and then receive the dopant from the source layer 136a to form a second contact CH2. The method may effectively form the second contact CH2 even when a lower temperature and less time are applied due to a short moving distance of the dopant, adjust the width of the second contact CH2 in the vertical direction (Z direction) by adjusting the concentration of the dopant, and improve the dispersion of the dopant included in the second contact CH2. Thus, the present disclosure may provide the semiconductor device 10 with improved electrical reliability and a method of manufacturing the semiconductor device 10.

FIGS. 14A through 14C are cross-sectional views illustrating portions of a method of manufacturing a semiconductor device. The method of manufacturing a semiconductor device described with reference to FIGS. 14A through 14C may be substantially the same as that described above with reference to FIGS. 3A through 13D, and may be applied in place of the processes described above with reference to FIGS. 13B through 13D. Accordingly, for convenience of description, the processes described with reference with FIGS. 3 through 13A are omitted, and differences from the description given above are mainly described.

Referring to FIG. 14A, a source layer 136b may be formed on the resultant product of FIG. 13A. The source layer 136b may include doped polysilicon, and the dopant included in the source layer 136b may have a certain concentration in the entire region.

Referring to FIG. 14B, a preliminary second contact pattern CP2′ having a certain concentration may be formed on the vertical channel pattern CH due to the dopant diffused from the source layer 136b, and the sacrificial layer SL may be removed again.

The dopant included in the preliminary second contact pattern CP2′ may have been moved from the source layer 136b by using, for example, an ion implantation process, but the present disclosure is not limited thereto. In some implementations, the dopant included in the preliminary second contact pattern CP2′ may include phosphorus (P).

In some implementations, the concentration of the dopant included in the preliminary second contact pattern CP2′ may be less than an average concentration of the dopant included in the second contact pattern CP2 in FIG. 13C.

Referring to FIG. 14C, the bit line BL including the capping insulating pattern 170 and the first, second, and third conductive lines 160A, 160B, and 160C may be formed on the resultant product of FIG. 14B.

The bit line BL may be formed to extend in the first horizontal direction (X direction). The bit line BL may extend in the first horizontal direction (X direction), and may be formed in plurality apart from each other in the second horizontal direction (Y direction) crossing the first horizontal direction (X direction).

The first conductive line 160A may include doped polysilicon, and the dopant may further move from the doped polysilicon included in the first conductive line 160A to the preliminary second contact pattern CP2′, and the concentration of the dopant included in the preliminary second contact pattern CP2′ may increase.

Referring to FIG. 2 again, the second contact pattern CP2, in which the concentration of the dopant increases farther away from the upper surface of the handling substrate HS due to an occurrence of the concentration gradient in the preliminary second contact pattern CP2′ due to the dopant diffused from the first conductive line 160A, may be obtained, the handling substrate HS may be removed from the resultant product of FIG. 14C, and then, the data storage pattern DSP may be formed under the contact pattern layer BCL. The data storage pattern DSP may be electrically connected to the plurality of vertical channel patterns CH.

By using the method of manufacturing the semiconductor device 10 described above, the semiconductor device 10 may be manufactured. Compared to the method described with reference to FIGS. 13A through 13D, in which the second contact pattern CP2, having a higher dopant concentration as the vertical level thereof increases due to the dopant supplied by the source layer 136a, is formed, the method of manufacturing described with reference to FIGS. 14A through 14D may be different from that the preliminary second contact pattern CP2′ including the dopant having a relatively low concentration due to the dopant supplied by the source layer 136b is formed, and the second contact pattern CP2, having a higher concentration closer toward the first conductive line 160A by receiving additional dopant from the first conductive line 160A, is formed.

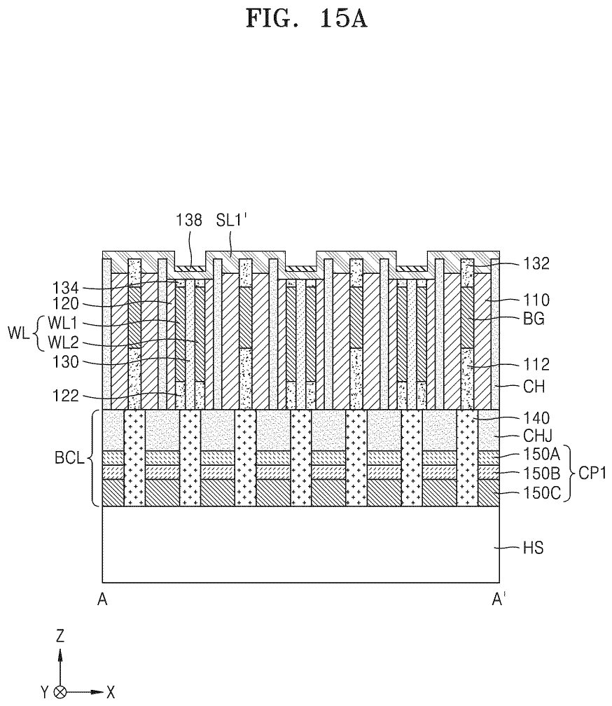

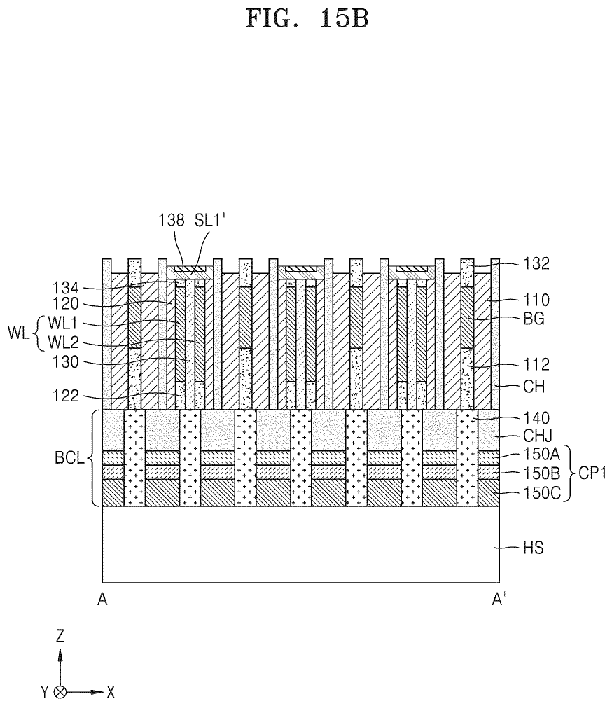

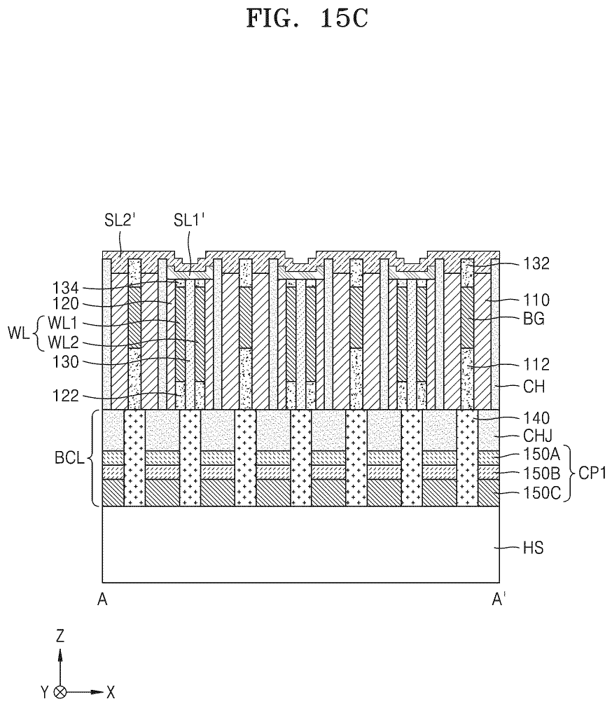

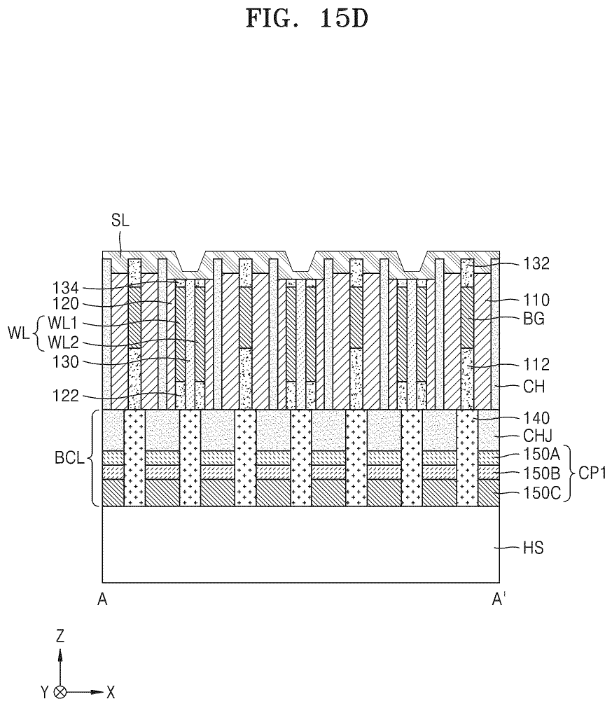

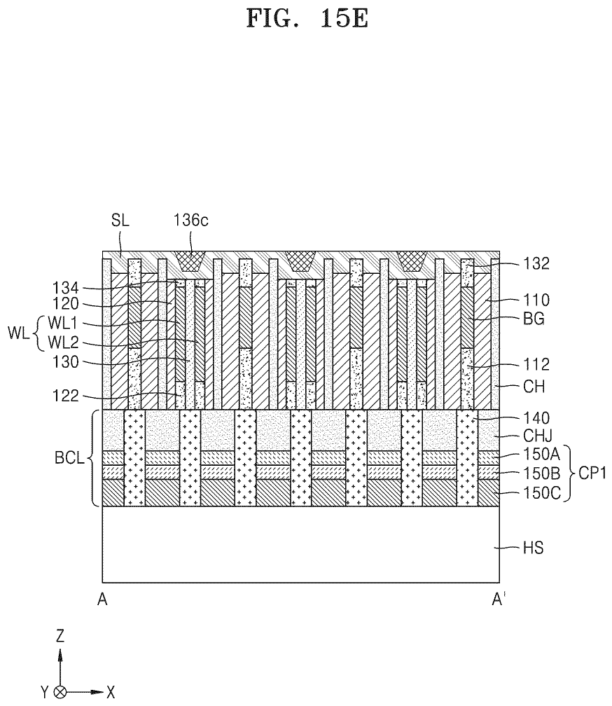

FIGS. 15A through 15E are cross-sectional views illustrating portions of a method of manufacturing a semiconductor device. Hereinafter, the method of manufacturing a semiconductor device described with reference to FIGS. 15A through 15E may be substantially the same as that described above with reference to FIGS. 3 through 13A, 13C, and 13D, and may be applied in place of the processes described above with reference to FIG. 13B. Accordingly, for convenience of description, the processes described with reference with FIGS. 3 through 13A are omitted, and differences from the description given above are mainly described.

Referring to FIG. 15A, an oxide layer 138 having a certain thickness may be formed on a portion of a first sacrificial layer SL1′ in FIG. 13A. In some implementations, the oxide layer 138 may be formed on an upper surface of a first sacrificial layer SL1′ formed in a region between adjacent vertical channel patterns CH with the first and second word lines WL1 and WL2 arranged therebetween. A vertical level of an upper surface of the oxide layer 138 may be less than a vertical level of the uppermost surface of a first sacrificial layer SL1′.

Referring to FIG. 15B, a portion of the first sacrificial layer SL1′ may be removed. By using the process described above, upper surfaces of a plurality of channel patterns CH, the first insulating pattern 110, and the second back gate insulating layer 132 may be exposed again. The upper surface of the remaining first sacrificial layer SL1′ may be arranged on the same plane as the upper surface of the oxide layer 138. In some implementations, the remaining first sacrificial layer SL1′ may have a cross-section in the first horizontal direction (X direction) left in a U-shape.

Referring to FIG. 15C, the oxide layer 138 may be removed, and a second sacrificial layer SL2′ covering the first sacrificial layer SL1′. In some implementations, all of the first and second sacrificial layers SL1′ and SL2′ may include SiGe, but the present disclosure is not limited thereto.

Referring to FIG. 15D, the sacrificial layer SL having a slope may lastly remain due to the first and second sacrificial layers SL1′ and SL2′.

In some implementations, the sacrificial layer SL may have a flat upper surface formed in parallel with the upper surface of the handling substrate HS in a region between the back gate electrode BG and the vertical channel patterns CH facing the back gate electrode BG and having the back gate electrode BG therebetween, but in a region between the vertical channel patterns CH facing each other with the first and second word lines WL1 and WL2 therebetween, the thickness of the sacrificial layer SL may be formed to decrease closer toward the third insulating pattern 130 arranged between the first and second word lines WL1 and WL2. In other words, the upper surface of the sacrificial layer SL may not have the same vertical thickness in all regions, and may be formed in a shape similar to a shape having a concave recess of an inverted trapezoidal shape on the third insulating pattern 130.

Although the sacrificial layer SL in FIG. 15D is described as formed by performing the deposition operation thereon twice with reference to FIGS. 15A and 15C, preliminary sacrificial layers may also be deposited three times or more to form the sacrificial layer SL having a slope. Alternatively, the sacrificial layer SL having a slope may also be formed by performing the deposition process only once. The process described with reference to FIGS. 15A through 15C may be merely an example of one of cases in which the upper surface of the sacrificial layer SL may have a slope, and a method of forming the sacrificial layer SL is not limited thereto.

Referring to FIG. 15E, a source layer 136c filling a space between the sacrificial layers SL may be formed. The source layer 136c may include doped polysilicon, and the dopant included in the source layer 136c may have a certain concentration in the entire region.

In addition, referring to FIG. 13C, the second contact pattern CP2 having a certain concentration gradient may be formed on the vertical channel pattern CH due to the dopant diffused from the source layer 136c, and the sacrificial layer SL may be removed again.

The dopant included in the second contact pattern CP2 may move from the source layer 136c by using, for example, an ion implantation process, but the present disclosure is not limited thereto. In some implementations, the dopant included in the second contact pattern CP2 may include phosphorus (P).

In some implementations, the dopant included in the second contact pattern CP2 may be included at a higher concentration farther away from the upper surface of the handling substrate HS in the vertical direction (Z direction). Although the dopant included in the source layer 136c may have a certain concentration, the upper portion of the second contact pattern CP2, where an amount of dopant diffused due to the source layer 136c being formed in an inverted trapezoidal shape on the sacrificial layer SL is large, may include a relatively high concentration of dopant, and a lower portion of the second contact pattern CP2 having a small amount of diffused dopant may include a relatively low concentration of the dopant.

Subsequently, referring to FIGS. 13D and 2, as described above, the semiconductor device 10 may be manufactured by forming the capping insulating pattern 170 and the bit line BL on the resultant product of FIG. 13C, removing the handling substrate HS, and forming the data storage pattern DSP under the contact pattern layer BCL.

Compared to the method described with reference to FIG. 13B, in which the second contact pattern CP2, having a higher dopant concentration as the vertical level thereof increases due to the dopant supplied by the source layer 136a, in which the dopant concentration increases as the vertical level thereof increases, is formed, the method of manufacturing described with reference to FIGS. 15A through 15E may be different from that, instead of forming the source layer 136c having a certain concentration in the entire region, a distance and/or amount of the dopant diffusing to the upper portion of the vertical channel pattern CH is adjusted by differentiating the thickness of the sacrificial layer SL depending on regions, and as a result, a second contact pattern CP2 having the concentration gradient is formed.

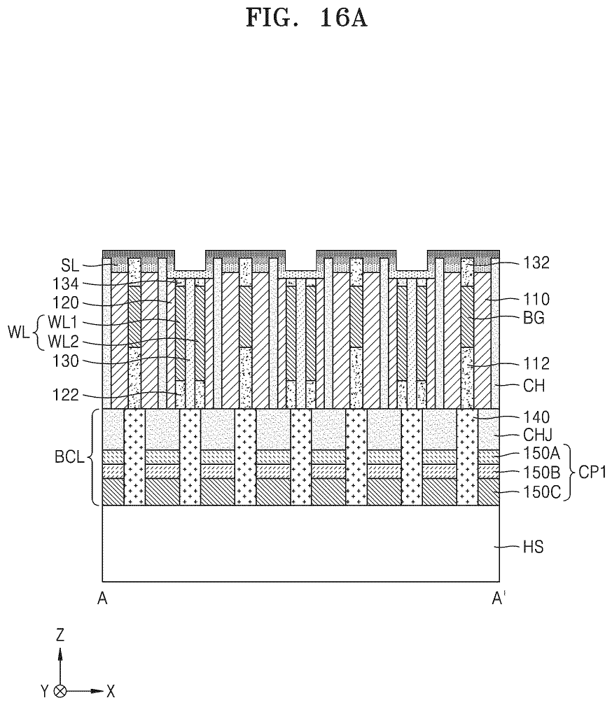

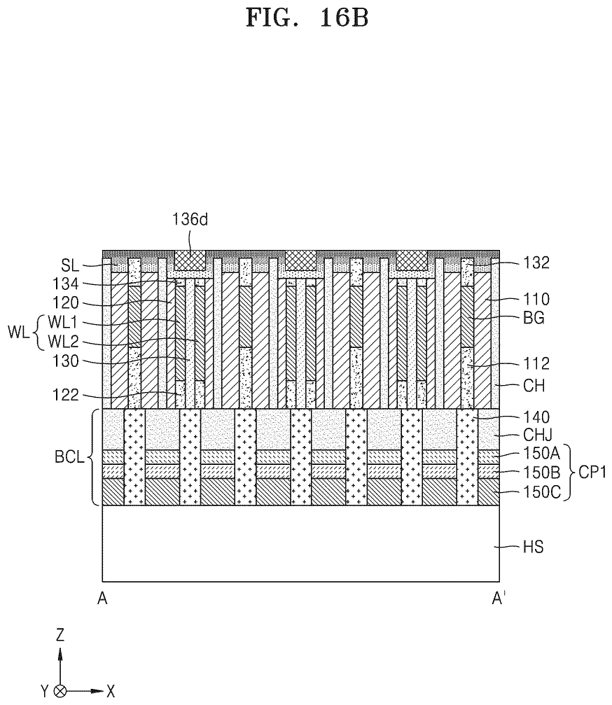

FIGS. 16A and 16B are cross-sectional views illustrating portions of a method of manufacturing a semiconductor device. Hereinafter, the method of manufacturing a semiconductor device described with reference to FIGS. 16A and 16B may be substantially the same as that described above with reference to FIGS. 3 through 12, 13C, and 13D, and may be applied in place of the processes described above with reference to FIGS. 13A and 13B. Accordingly, for convenience of description, the processes described with reference with FIGS. 3 through 12 are omitted, and differences from the description given above are mainly described.

Referring to FIG. 16A, the sacrificial layer SL may be formed on the resultant product of FIG. 12. In some implementations, the sacrificial layer SL may include SiGe.

Unlike the sacrificial layer SL in FIG. 13A, the sacrificial layer SL in FIG. 16A may have different concentration of Ge depending on the region. For example, the concentration of Ge included in SiGe of the sacrificial layer SL may further increase away from the handling substrate HS in the sacrificial layer SL in the vertical direction (Z direction). The difference in the concentration of Ge included in the sacrificial layer SL may affect diffusion of the dopant, as to be described below.

The sacrificial layer SL may be formed to have a thickness to cover all upper surfaces of the first insulating pattern 110, the second insulating pattern 120, the third insulating pattern 130, the second back gate insulating layer 132, the second buried pattern 134, and the vertical channel pattern CH. In some implementations, the vertical level of the upper surface of the sacrificial layer SL formed in the space between vertical channel patterns CH apart from each other in the first horizontal direction (X direction) with the first and second word lines WL1 and WL2 arranged therebetween may be less than the vertical level of the upper surface of the sacrificial layer SL formed in the space between vertical channel patterns CH apart from each other in the first horizontal direction (X direction) with the back gate electrode BG arranged therebetween.

Referring to FIG. 16B, a source layer 136d may be formed on the resultant product of FIG. 16A. The source layer 136d may include doped polysilicon, and the dopant included in the source layer 136d may have a certain concentration in the entire region.

Referring to FIG. 13C, the second contact pattern CP2 having a constant concentration gradient may be formed on the vertical channel pattern CH due to the dopant diffused from the source layer 136d, and the sacrificial layer SL may be removed again.

The dopant included in the second contact pattern CP2 may move from the source layer 136d by using, for example, an ion implantation process, but the present disclosure is not limited thereto. In some implementations, the dopant included in the second contact pattern CP2 may include phosphorus (P).

In some implementations, the dopant included in the second contact pattern CP2 may be included at a higher concentration farther away from the upper surface of the handling substrate HS in the vertical direction (Z direction). This phenomenon may be generated due to the concentration gradient of the sacrificial layer SL, and although the concentration of the dopant included in the source layer 136d may be constant, because the concentration of Ge included in SiGe of the sacrificial layer SL may increase as the position of Ge moves vertically upward, the diffusion speed and the amount of the dopant may be affected by the increase in the concentration, and as a result, the dopant included in the second contact pattern CP2 may be included at a higher concentration as the positions thereof moves vertically upward. The subsequent processes may be performed in the same manner as described with reference to FIGS. 13D and 2, and the semiconductor device 10 may be manufactured.

Compared to the method described with reference to FIGS. 13A and 13B, in which the second contact pattern CP2, having a higher dopant concentration as the vertical level thereof increases due to the dopant supplied by the source layer 136a, in which the dopant concentration increases as the vertical level thereof increases, is formed, the method of manufacturing described with reference to FIGS. 16A through 16B may be different from that, although the dopant concentration included in the source layer 136d is uniform in the entire region, a diffusion speed and amount of the dopant diffused from the source layer 136d is adjusted by increasing the concentration of Ge included in the sacrificial layer SL as the vertical level of the sacrificial layer SL increases, and as a result, the second contact pattern CP2, having a higher dopant concentration as the vertical level of the Ge increases, is formed.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to implementations thereof, it will be understood that various change in form and details may be made therein without departing from the spirit and scope of the following claims.

What is claimed is:

1. A method of manufacturing a semiconductor device, the method comprising:
forming, on a first surface of a substrate, a plurality of vertical channel patterns, a word line, and a back gate electrode, the plurality of vertical channel patterns being apart from each other in a first horizontal direction, the word line and the back gate electrode extending in a second horizontal direction crossing the first horizontal direction, the substrate including a second surface facing the first surface;
forming a contact pattern layer and an isolation insulating layer, the contact pattern layer including a plurality of first contact patterns contacting first end portions of the plurality of vertical channel patterns, the isolation insulating layer being between the plurality of first contact patterns;
inverting the substrate to orient the second surface of the substrate upward;
removing the substrate and etching an insulating pattern until second end portions of the plurality of vertical channel patterns are exposed;
forming a sacrificial layer surrounding a plurality of sidewalls and a plurality of upper surfaces of the plurality of vertical channel patterns, the plurality of sidewalls and the plurality of upper surfaces being exposed;
forming a source layer provided at a plurality of spaces defined by the sacrificial layer;
forming a second contact pattern on the second end portions of the plurality of vertical channel patterns; and
removing the sacrificial layer and forming a bit line extending on the second end portions of the plurality of vertical channel patterns in the first horizontal direction,
wherein the source layer is formed in a region where the source layer is offset from the plurality of vertical channel patterns in a plan view, and
wherein a dopant included in the second contact pattern diffuses from the source layer.

2. The method of claim 1, wherein the sacrificial layer comprises silicon germanium.

3. The method of claim 1,
wherein the second contact pattern is electrically connected with the bit line, and
wherein a concentration of the dopant comprised in the second contact pattern decreases in a direction farther away from a lower surface of the bit line.

4. The method of claim 3, wherein the dopant comprises phosphorus.

5. The method of claim 1, wherein the sacrificial layer is formed with a slope on a plurality of sidewalls of the sacrificial layer.

6. The method of claim 5, wherein a thickness in the first horizontal direction of the sacrificial layer decreases toward an upper surface of the plurality of vertical channel patterns.

7. The method of claim 5, wherein forming the sacrificial layer comprises performing depositing a preliminary sacrificial layer multiple times.

8. The method of claim 1, wherein the sacrificial layer is formed with an increasing germanium concentration in a direction toward an upper surface of the plurality of vertical channel patterns.

9. The method of claim 1, wherein a concentration of dopants comprised in the source layer increases in a direction toward an upper surface of the plurality of vertical channel patterns.

10. The method of claim 1,
wherein the bit line comprises a conductive line including doped polysilicon, and
wherein an additional dopant is supplied from the conductive line to the second contact pattern.

11. A method of manufacturing a semiconductor device, the method comprising:
forming, on a first surface of a substrate, a plurality of vertical channel patterns, a word line, and a back gate electrode, the plurality of vertical channel patterns being apart from each other in a first horizontal direction, the word line extending in a second horizontal direction crossing the first horizontal direction, the word line being between a first vertical channel pattern and a second vertical channel pattern among the plurality of vertical channel patterns, the first vertical channel pattern and the second vertical channel pattern facing each other, the back gate electrode extending in the second horizontal direction, the back gate electrode being between the second vertical channel pattern and a third vertical channel pattern among the plurality of vertical channel patterns, the second vertical channel pattern and the third vertical channel pattern facing each other, the substrate including a second surface facing the first surface;
forming a contact pattern layer and an isolation insulating layer, the contact pattern layer including a plurality of first contact patterns contacting first end portions of the plurality of vertical channel patterns, the isolation insulating layer being between the plurality of first contact patterns;
inverting the substrate to orient the second surface of the substrate upward;
removing the substrate and etching an insulating pattern until second end portions of the plurality of vertical channel patterns are exposed;
forming a sacrificial layer surrounding a plurality of sidewalls and a plurality of upper surfaces of the plurality of vertical channel patterns, the plurality of sidewalls and the plurality of upper surfaces being exposed; and
forming, on the sacrificial layer, a source layer provided at a space between an end portion of the first vertical channel pattern and an end portion of the second vertical channel pattern,
wherein the source layer comprises a dopant, and the dopant passes through the sacrificial layer from the source layer, moves to the end portion of the second vertical channel pattern, and forms a second contact pattern at the end portion of the second vertical channel pattern.

12. The method of claim 11, comprising forming a bit line extending on the second contact pattern in the first horizontal direction.

13. The method of claim 11, wherein the dopant comprises phosphorus, and the sacrificial layer comprises silicon germanium.

14. The method of claim 11, wherein a concentration of the dopant comprised in the second contact increases in a direction away from the end portion of the second vertical channel pattern.

15. The method of claim 11, wherein a concentration of the dopant comprised in the second contact pattern increases in a direction from a center toward sidewalls of the second contact pattern.

16. The method of claim 11, wherein a concentration of the dopant comprised in the source layer increases in a direction toward upper surfaces of the plurality of vertical channel patterns.

17. The method of claim 11, wherein a thickness in the first horizontal direction of the sacrificial layer decreases toward upper surfaces of the plurality of vertical channel patterns.

18. The method of claim 11, wherein the sacrificial layer is formed with an increasing germanium concentration in a direction toward upper surfaces of the plurality of vertical channel patterns.

19. A method of manufacturing a semiconductor device, the method comprising:
forming, on a first surface of a substrate, a plurality of vertical channel patterns, a word line, and a back gate electrode, the plurality of vertical channel patterns being apart from each other in a first horizontal direction, the word line extending in a second horizontal direction crossing the first horizontal direction, the word line being between a first vertical channel pattern and a second vertical channel pattern among the plurality of vertical channel patterns, the first vertical channel pattern and the second vertical channel pattern facing each other, the back gate electrode extending in the second horizontal direction, the back gate electrode being between the second vertical channel pattern and a third vertical channel pattern among the plurality of vertical channel patterns, the second vertical channel pattern and the third vertical channel pattern facing each other, the substrate including a second surface facing the first surface;
forming a contact pattern layer and an isolation insulating layer, the contact pattern layer including a plurality of first contact patterns contacting first end portions of the plurality of vertical channel patterns, the isolation insulating layer being between the plurality of first contact patterns;
inverting the substrate to orient the second surface of the substrate upward;
removing the substrate and etching an insulating pattern until second end portions of the plurality of vertical channel patterns are exposed; and
forming a second contact pattern, wherein a dopant concentration of the second contact pattern increases as vertical levels of the second end portions of the plurality of vertical channel patterns increase,
wherein forming the second contact pattern comprises:
forming a sacrificial layer in a space between a plurality of sidewalls of the plurality of vertical channel patterns;
forming a source layer provided at a space defined by the sacrificial layers; and
diffusing a dopant from the source layer to the second contact pattern.

20. The method of claim 19, wherein the dopant comprises phosphorus, and the sacrificial layer comprises silicon germanium.
